(19) United States
(12) Patent Application Publication
(10) Pub. No.: US 2026/0313991 A1
(43) Pub. Date: Oct. 8, 2026

(54) STRESS LINER INTEGRATION IN MEMORY DEVICES

(71) Applicant: Micron Technology, Inc., Boise, ID (US)

(72) Inventors: Bingwu Liu, Meridian, ID (US); Shivani Srivastava, Boise, ID (US); Dan Mihai Mocuta, Boise, ID (US)

(21) Appl. No.: 19/172,071

(22) Filed: Apr. 7, 2025

(51) Int. Cl. H10D 62/17; H10B 12/00; H10D 62/00

(52) U.S. Cl. CPC H10D 62/235; H10B 12/09; H10B 12/50; H10D 62/01

(57) ABSTRACT

A variety of applications can include an electronic device having one or more memory devices that include transistors in a periphery to a memory array of the memory device, where one or more of the transistors includes a stress liner near channel structures of the one or more transistors, while other transistors in the periphery do not have a stress liner near their channel structures. The stress liner can be formed after transistors have been formed in the periphery and memory cells have been formed in the memory array and before contacts to the transistors have been patterned. The transistors for which a stress liner is being formed can be uncovered, while maintaining the transistors without a stress liner covered. Transistors having an associated stress liner can be n-type transistors with a tensile stress liner or p-type transistors with a compressive stress liner.

### FIELD OF THE DISCLOSURE

Embodiments of the disclosure relate generally to electronic devices and systems, and more specifically, to memory devices, components of memory devices, and formation thereof.

### BACKGROUND

Memory devices are typically provided as internal, semiconductor, integrated circuits in computers or other electronic devices. There are many different types of memory devices, including volatile and non-volatile memory devices. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design or fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a schematic of an example memory device that can include an architecture in which selected transistors in the periphery to the memory array of the memory device are structured with a stress liner, in accordance with various embodiments.

FIG. 2 is a flow diagram of features of an example method of forming a memory device, in accordance with various embodiments.

FIG. 3 is a flow diagram of features of another example method of forming a memory device, in accordance with various embodiments.

FIGS. 4-16 illustrate an example process flow for fabricating a memory device having a selected transistor in the periphery to the memory array of a memory device structured with a stress liner, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

A stress liner provided for a transistor is widely used to boost the direct current (DC) performance of a complementary metal-oxide semiconductor (CMOS) device by changing the channel stress through deposition of a stress liner. Usually, the stress liner is a nitride liner, which is provided with tensile stress for an n-type MOS field effect transistor (FET), which can be referred to as a NFET or a NMOS transistor, and is provided with compressive stress for a p-type MOSFET, which can be referred to as a PFET or a PMOS transistor. To maximize the stress effect, the stress liner should be as close to the channel structure of the respective MOSFET as possible. The stress liner, after formation proximal to the channel structure, should not be damaged during downstream processing. This can be an issue in a fabrication flow for a stress liner in a memory device.

A memory die, such as a DRAM circuit, includes array of memory cells and a periphery to the array. In fabrication, the memory cells of the array and transistors in the periphery to the array can be formed in an integrated process flow. While selected transistors in the periphery are designed with a stress film to boost performance, a stress film is typically not implemented in the array. The selected transistors can include, but are not limited to, transistors of CMOS devices in the periphery. Furthermore, in the integrated process, the gate height of periphery transistors is typically limited by a height of the array. These height limits can make the processing difficult to keep a formed stress liner continuous, where no stress effect remains for non-continuous stress liners after the full processing of the DRAM.

In various embodiments, an integration process flow can be implemented to enable a stress liner process that is compatible with an integrated memory die fabrication such as, but not limited to, compatibility with a periphery-array integration process flow for a memory device die. The memory device die can be a DRAM die. In this compatible process, formation of the stress liner is moved from traditional post source/drain (SD) formation to post memory cell formation and pre contact formation. After formation of periphery transistors and array memory cells, openings to selected specific transistors to which stress liners are to be formed are made before contact patterning. The openings can be made by removing an interlayer dielectric (ILD) and portions of a spacer corresponding to the selected specific transistors. After forming the openings, the stress liner can be deposited and another ILD formed on the stress liner to the selected specific transistor. Formation of the ILD on the stress liner can be followed by normal contact processing.

This process can be implemented with a NMOS transistor as a selected transistor in the periphery. With a NMOS transistor being the specific transistor, the process can be implemented with a tensile film. This process can be implemented with a PMOS transistor as a selected transistor in the periphery. With a PMOS transistor being the specific transistor, the process can be implemented with a compressive film. Depending on the selected specific transistor in the periphery, openings formed for stress liner formation depends on the selected transistor, and the stress processing following the openings is a specific-type transistor stress procedure. This process in the integrated process flow, after forming the periphery transistors and the memory cells, an also be implemented on both NMOS transistor and PMOS transistor, with the process performed on one type device first and repeated for the other type device. This process implemented in an integrated process flow for a memory device retains the benefit of stress performance boost for transistor, while maintaining integrated process flow of array and periphery to the array. Such stress liner process flows are compatible with DRAM processing, but can be implemented in other electronic devices.

In various embodiments, a memory device can include an array of memory cells and a periphery to the array, where the periphery includes a transistor with a stress liner close to the channel structure of the transistor. The transistor can include a gate stack having a gate dielectric on the channel structure of the transistor, a polysilicon gate on the gate dielectric, and a metal on the polysilicon gate. Other configurations of a gate stack can be used. A dielectric cap can be structured on top of and contacting the gate stack. A dielectric sidewall can be structured vertically along the gate stack. A stress liner can be located on and contacting the dielectric cap and the dielectric sidewall. An interlayer dielectric can be located on the stress liner that is on the dielectric cap. The interlayer dielectric can extend into the array. The interlayer dielectric can also be located on the data lines of the memory array.

Variations of such a memory device and its features can include a number of different embodiments and features that may be combined depending on the application of such memory devices, the format of such memory devices, and/or the architecture in which such memory devices are implemented. Features of such memory devices can include the memory device having a second transistor in the periphery, where the second transistor has a second gate stack without an associated stress liner. A second dielectric cap can be structured on the second gate stack, and a second interlayer dielectric can be structured on and contacting the second dielectric cap. The second interlayer dielectric can be a portion of the interlayer dielectric that extends from the stress liner to the array. The interlayer dielectric on the stress liner can have a vertical thickness less than a vertical thickness of the second interlayer dielectric. A top surface of the interlayer dielectric that is situated over the transistor and the second transistor can be at a common vertical level that is the same in the periphery and the array.

Variations of such a memory device and its features can include the transistor having source/drains connected to vertical contacts that extend through the stress liner. The transistor can be a n-type field effect transistor and the stress liner can be a tensile stress liner. Alternatively, the transistor can be a p-type field effect transistor and the stress liner can be a compressive stress liner. The stress liner can include a nitride. The dielectric sidewall along the gate stack of the transistor can include two layers of dielectric material. The two layers of dielectric material can include a nitride. The two layers can be composed of a common material formed at different times in the formation of the transistor structure.

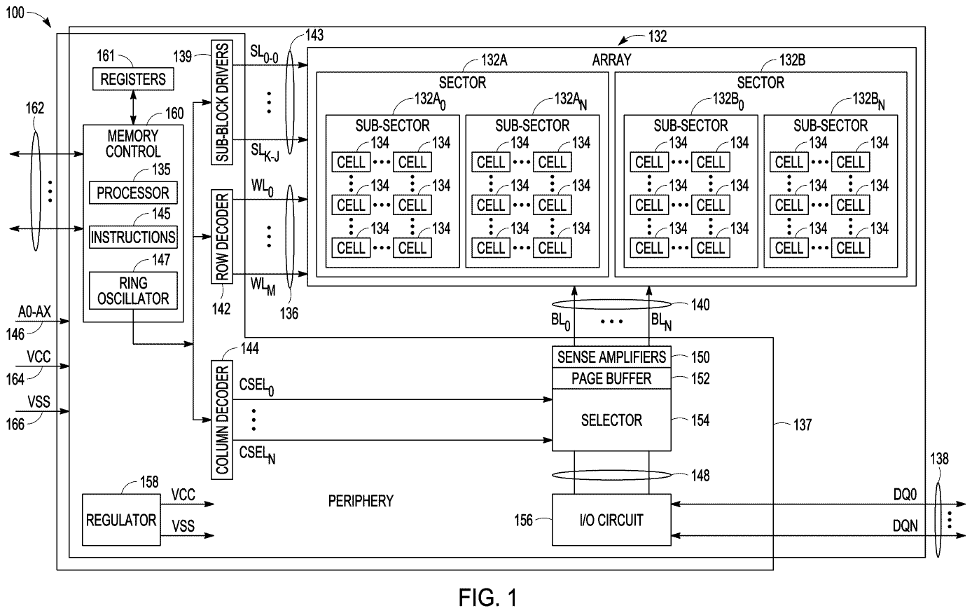

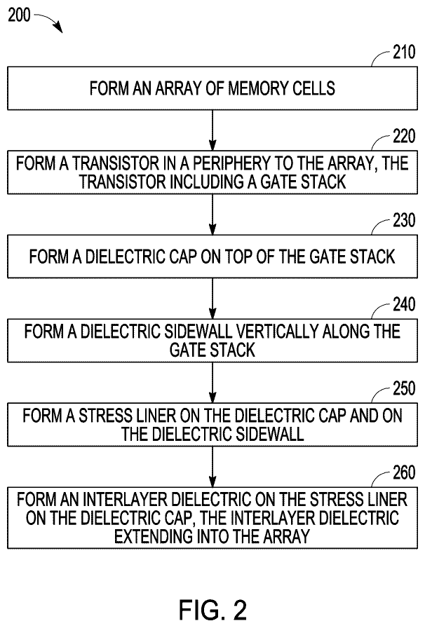

FIG. 1 is a schematic of an example memory device 100 that can include an architecture in which selected transistors in a periphery 137 to a memory array 132 of memory device 100 can be structured with a stress liner. Memory device 100 can be a DRAM. Memory device 100 can include memory array 132 having a plurality of memory cells 134, periphery 137 to memory array 132, sense amplifiers 150, and one or more circuits or components to provide communication with memory array 132 or perform one or more memory operations on memory array 132. Memory device 100 can include one or more CMOS devices in the periphery and one or more CMOS devices in sense amplifiers 150 constructed having a structure as discussed with respect to FIGS. 2-16. Memory cells 104 can be formed coupled to data lines, where these data lines couple to or are a part of data lines (BLs) 140 coupled to sense amplifiers 150. Memory device 100 can be a memory die, for example, a DRAM memory die. Memory device 100 can include a row decoder 142, a column decoder 144, sub-block drivers 139, sense amplifiers 150, a page buffer 152, a selector 154, an I/O circuit 126, and a memory controller 160.

Memory controller 160 can include processing circuitry, including one or more processors 135, and can be configured to perform operations of the memory device 100 by executing instructions 145. Memory controller 160 can be coupled to registers 161 that can contain parameter data for memory controller 160. For purposes of the present example, instructions 145 may be performed by memory within or dedicated to memory controller 160. In other examples, at least some portion of the instructions executed by memory controller 160 may be stored in other memory structures and loaded, for example, into local (memory controller) memory for execution by the memory controller 160. Memory controller 160 can include a ring oscillator (RO) 147.

Memory cells 104 of memory array 132 can be arranged in blocks, such as first and second blocks 132A, 132B. Each block can include sub-blocks. For example, first block 132A can include first and second sub-blocks 132A₀, 132A_{N}, and second block 132B can include first and second sub-blocks 132B₀, 132B_{N}. Each sub-block can include a number of physical pages, with each page including a number of memory cells 134. Although illustrated herein as having two blocks, with each block having two sub-blocks, and each sub-block having a number of memory cells 134, in other examples, the memory array 132 can include more or fewer blocks, sub-blocks, memory cells, etc. In other examples, the memory cells 134 can be arranged in a number of rows, columns, pages, sub-blocks, blocks, etc., and accessed using, for example, access lines 136, data lines 140, or one or more select gates, source lines, etc.

Memory controller 160 can control memory operations of the memory device 100 according to one or more signals or instructions received on control lines 162, including, for example, one or more clock signals or control signals that indicate a desired operation (e.g., write, read, erase, etc.), or address signals (A0-AX) received on one or more address lines 146. One or more devices external to memory device 100 can control the values of the control signals on control lines 162 or address signals on address line 146. Examples of devices external to memory device 100 can include, but are not limited to, a host, an external memory controller, a processor, or one or more circuits or components not illustrated in FIG. 1.

Memory device 100 can use access lines 146 and data lines 140 to transfer data to (e.g., write or erase) or from (e.g., read) one or more of memory cells 134. Row decoder 142 and column decoder 144 can receive and decode address signals (A0-AX) from address lines 146, determine which of memory cells 134 are to be accessed, and provide signals to one or more of access lines 136 (e.g., one or more of a plurality of access lines (WL₀-WL_{M})) or data lines 140 (e.g., one or more of a plurality of data lines (BL0-BLN)). Memory device 100 can include sense circuitry, such as sense amplifiers 150, configured to determine the values of data on (e.g., read), or to determine the values of data to be written to, memory cells 134 using data lines 140.

One or more devices external to the memory device 100 can communicate with memory device 100 using I/O lines (DQ0-DQN) 138, address lines 146 (A0-AX), or control lines 162. I/O circuit 156 can transfer values of data in or out of memory device 100, such as in or out of page buffer 152 or memory array 132, using I/O lines 138, according to, for example, control lines 162 and address lines 146. Page buffer 152 can store data received from the one or more devices external to memory device 100 before the data is programmed into relevant portions of memory array 132, or can store data read from memory array 132 before the data is transmitted to the one or more devices external to the memory device 100.

Column decoder 144 can receive and decode address signals (A0-AX) into one or more column select signals (CSEL₁-CSEL_{N}). Selector 154 (e.g., a select circuit) can receive the column select signals (CSEL₁-CSEL_{N}) and select data in page buffer 152 representing values of data to be read from or to be programmed into memory cells 134. Selected data can be transferred between page buffer 152 and the I/O circuit 126 using second data lines 148.

Memory controller 160 can receive positive and negative supply signals, such as a supply voltage (Vcc) 164 and a negative supply (Vss) 166 (e.g., a ground potential) with respect to Vcc, from an external source or supply (e.g., an internal or external battery, an alternating current (AC) to direct current (DC) converter, etc.). In certain examples, memory controller 160 can include a regulator 158 to internally provide positive or negative supply signals.

Based on an address provided by a user device, memory controller 160 can select any one sub-block or all sub-blocks. Memory controller 160 can generate the sub-block address to the sub-block drivers 139 and select any one sub-block or all sub-blocks. Memory controller 160 can send the WL information to the row decoder 142 and a column address to the column decoder 144.

Sub-block drivers 139 can include a number of independent drivers that generate signals to select lines 143 SL₀₋₀ . . . SL_{K-J}. These select lines can be coupled to different select devices in different blocks. Multiple input signals can be assigned to each individual driver, depending on the different voltages designed for operation of the respective driver during erase operations, program operations, and read operations. From the sub-block drivers 139, appropriate operational signals can be sent to the memory array 132 via the select lines 143 (SL_{(sub-block #)-(SGD # or SGS #)}) SL₀₋₀ . . . SL_{K-J}.

FIG. 2 is a flow diagram of features of an example embodiment of a method 200 of forming a memory die. At 210, an array of memory cells is formed. At 220, a transistor is formed in a periphery to the array, where the transistor includes a gate stack. Other similar transistors to be formed with stress liners in the periphery can be formed and transistors designed without a corresponding stress liner can be formed. The array of memory cells and the transistor method can be performed together in an integrated process.

At 230, a dielectric cap is formed on top of the gate stack. At 240, a dielectric sidewall is formed vertically along the gate stack. The dielectric cap and the dielectric sidewall can be formed in a common procedure. At 250, a stress liner is formed on the dielectric cap and on the dielectric sidewall. At 260, an interlayer dielectric is formed on the stress liner on the dielectric cap, with the interlayer dielectric extending into the array.

Variations of method 200 or methods similar to method 200 can include a number of different embodiments that may be combined depending on the application of such methods or the architecture or operation flow for which such methods are implemented. Such methods can include forming, in the periphery, one or more transistors without an associated stress liner, with the interlayer dielectric above the one or more transistors that are without an associated stress liner. The one or more transistors can include one or more peripheral devices and one or more pitch devices. Pitch devices include devices that can have dimensions aligned with the memory array, such as word line drivers, sense amplifiers, or other similar devices. Peripheral devices or circuitry include other logic-like device components that basically control the memory circuits of the memory device. Peripheral and pitch devices can include individual n-channel transistors, p-channel transistors, CMOS devices, or other devices.

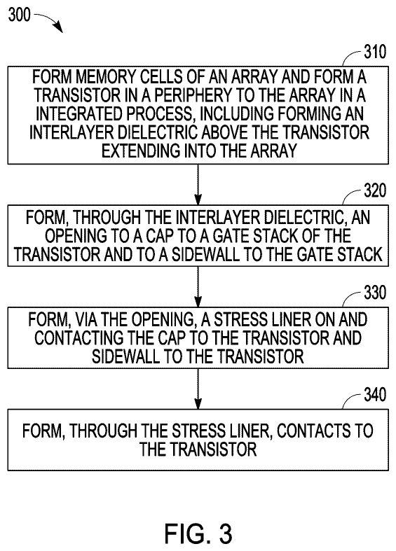

FIG. 3 is a flow diagram of features of an embodiment of an example method 300 of forming a memory device. At 310, memory cells of an array and a transistor in a periphery to the array are formed in an integrated process. An interlayer dielectric is formed above the transistor extending into the array in the integrated process. At 320, an opening to a cap to a gate stack of the transistor and to a sidewall to the gate stack is formed through the interlayer dielectric.

At 330, a stress liner is formed on and contacting the cap to the transistor and the sidewall to the transistor, via the opening. The stress liner can be formed as a nitride stress liner. Other materials can be used that provide a stress to the channel structure of the transistor.

At 340, contacts to the transistor are formed through the stress liner. The transistor can be formed as a n-type field effect transistor with the stress liner formed as a tensile stress liner. Alternatively, the transistor can be formed as a p-type field effect transistor with the stress liner formed as a compressive stress liner. Other transistors can be formed in the periphery with an associated stress liner in a common procedure with the transistor.

Variations of method 300 or methods similar to method 300 can include a number of different embodiments that may be combined depending on the application of such methods or the architecture or operation flow for which such methods are implemented. Such methods can include performing a number of procedures to form the transistor of method 300. These procedures can include forming one or more other transistors, in the periphery, with the interlayer dielectric above the one or more other transistors in an integrated process with forming the transistor and the interlayer dielectric, and maintaining the interlayer dielectric over the one or more other transistors during the forming of the opening to the cap and sidewall to the gate stack. The stress liner can be formed on the interlayer dielectric above the one or more other transistors when forming the stress liner on and contacting the cap and sidewall to the transistor. The stress liner can be removed from the interlayer dielectric above the one or more other transistors while maintaining the stress liner on and contacting the cap and sidewall to the transistor. A second interlayer dielectric can be formed on the stress liner, which is on and contacting the cap and sidewall to the transistor, and on the interlayer dielectric above the one or more other transistors, where the second interlayer dielectric extends into the array. Contacts can be formed through the second interlayer dielectric and through the interlayer dielectric to the one or more other transistors. Variations of method 300 or methods similar to method 300 can include forming the interlayer dielectric and the second interlayer dielectric on data lines to the memory cells of the array. Variations can include forming the one or more other transistors by forming a p-type field effect transistor with a silicon germanium channel and a pitch transistor in the periphery. A method of forming memory devices can include permutations of features of method 200 and method 300.

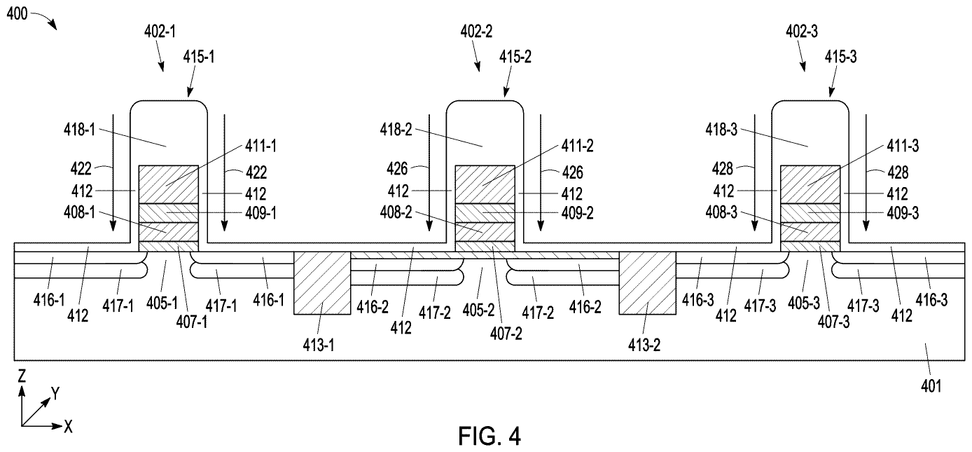

FIGS. 4-16 illustrate an embodiment of an example process flow for fabricating an memory device with a transistor in the periphery of the array of memory cells having an associated stress liner. Though FIGS. 4-16 illustrate three transistors as being fabricated, significantly more than three transistors can be formed in the periphery to an array of memory cells in fabricating a memory device using the processes illustrated in FIGS. 4-16. Though FIGS. 4-16 illustrate three transistors as being fabricated adjacent each other, these transistors can be formed in differ sections of the periphery to the memory device. The process flow of FIGS. 4-16 can be used in forming memory device 100 of FIG. 1.

FIG. 4 illustrates a cross-sectional view of a structure 400 after formation of gates stacks 415-1, 415-2, and 415-3 for transistors 402-1, 402-2, and 402-3, respectively, on a substrate 401. Formation of gate stack 415-1 on a channel structure 405-1 in substrate 401 has included forming a gate dielectric 407-1 on channel structure 405-1 and forming a gate 408-1 on gate dielectric 407-1. A polysilicon region 409-1 has been formed on gate 408-1 and a metal contact 411-1 has been formed on polysilicon region 409-1. Formation of gate stack 415-2 on a channel structure 405-2 in substrate 401 has included forming a gate dielectric 407-2 on channel structure 405-2 and forming a gate 408-2 on gate dielectric 407-2. A polysilicon region 409-2 has been formed on gate 408-2 and a metal contact 411-2 has been formed on polysilicon region 409-2. Formation of gate stack 415-3 on a channel structure 405-3 in substrate 401 has included forming a gate dielectric 407-3 on channel structure 405-3 and forming a gate 408-3 on gate dielectric 407-3. A polysilicon region 409-3 has been formed on gate 408-3 and a metal contact 411-3 has been formed on polysilicon region 409-3. A shallow trench insulator (STI) 413-1 has been formed separating the region for transistor 402-1 from the region for transistor 402-2. A STI 413-2 has been formed separating the region for transistor 402-2 from the region for transistor 402-3.

For a silicon substrate used for substrate 401, channel structures 405-1 and 405-3 can be silicon channel structures. A SiGe region has been formed at the surface region of substrate 401 between STIs 413-1 and 413-2. The SiGe region can be formed as an epitaxial growth from substrate 401. A channel structure can be constructed as a portion of the SiGe region formed in substrate 401, forming a SiGe channel structure (cSiGe) 405-2. STIs 413-1 and 413-2 can be oxides such as, but not limited to, a silicon oxide.

Gate dielectrics 407-1, 407-2, and 407-3 can be, but are not limited to, high-k dielectrics such as, but not limited to, high-k dielectric oxides. A high-k dielectric is a dielectric having a dielectric constant greater than the dielectric constant of silicon dioxide. Gate dielectrics 407-1, 407-2, and 407-3 can be multi-layer dielectrics. For example, a multi-layer dielectric can be realized by an interlayer (IL) such as, but not limited to, silicon oxide (SiO_{X}) and a high-k dielectric. Other formats for a multi-layer dielectric can be used. A high-k dielectric, in a single layer or in a multi-layer structure, can include hafnium oxide (HfO_{X}), zirconium oxide (ZrO_{X}), or other high-k dielectric.

Gates 408-1, 408-2, 408-3 can be metal gates. The metal of the metal gates can be tungsten, titanium, titanium nitride, or combinations thereof. With gates 408-1, 408-2, 408-3 on and contacting high-k gate dielectrics 407-1, 407-2, and 407-3, respectively, gate stacks 415-1, 415-2, and 415-3 include high-k metal gates (HKMGs). In an alternate design, gate stacks 415-1, 415-2, and 415-3 can include polysilicon gates rather than metal gates or HKMGs.

A spacer 412 has been formed on gate stacks 415-1, 415-2, and 415-3, on the exposed surfaces of structures along 415-1, 415-2, and 415-3, between gate stacks 415-1 and 415-2, and between gate stacks 415-2 and 415-3. Spacer 412 is on and contacting top surfaces of STIs 413-1 and 413-2 and the top surface the SiGe region between STIs 413-1 and 413-2 that extend outside of gate stack 415-2. Caps 418-1, 418-2, and 418-3 have been formed on the top surface of gate stacks 415-1, 415-2, and 415-3, respectively. Caps 418-1, 418-2, and 418-3 can be, but is not limited to, the composition of spacer 412. Spacer 412 and caps 418-1, 418-2, and 418-3 can be a nitride or other appropriate material to provide insulation and processing protection for gate stacks 415-1, 415-2, and 415-3. The nitride can be, but is not limited to, silicon nitride (SiN_{X}).

Lightly doped drain (LDD) region 416-1 and Halo region 417-1 have been formed for transistor 402-1. A LDD region is a narrow lightly doped region provided between a channel structure and more heavily doped source-drain regions of a MOSFET. Halo regions of a MOSFET are lightly doped regions near source-drain regions to reduce the width of the depletion region in the vicinity of source/substrate and drain/substrate junctions. LDD regions 416-2 and Halo regions 417-2 have been formed for transistor 402-2. LDD regions 416-3 and Halo regions 417-3 have been formed for transistor 402-3. Formation of these LDD and Halo region can be performed by implantation through spacer 412. For transistor 402-1, implants have been made by implant injection 422. For transistor 402-2, implants have been made by implant injection 426. For transistor 402-3, implants have been made by implant injection 428. Implant injection 428, implant injection 426, and implant injection 422 can have different characteristics from each other. The different characteristic can be based on the transistor types of transistors 402-1, 402-2, and 402-3 and the electronic device in which the transistors are being formed. For example, transistor 402-1 can be formed as a NMOS transistor, transistor 402-2 can be formed as a PMOS transistor with a cSiGe, and transistor 402-3 can formed as a NMOS transistor or a PMOS transistor without SiGe. Transistor 402-3 can be formed as a component of a pitch circuit of a periphery to a memory region of a memory device. Transistors 402-1 and 402-2 can be formed as a component of a periphery circuit of the periphery to the memory region of the memory device. The memory device can be, but is not limited to, a DRAM. With the LDD and Halo regions formed by implant through spacer 412 avoiding exposing the surfaces of substrate 401, STIs 413-1 and 413-2, and the SiGe region between STIs 413-1 and 413-2, surface oxidation of the active area for transistors 402-1, 402-2, and 402-3 can be avoided.

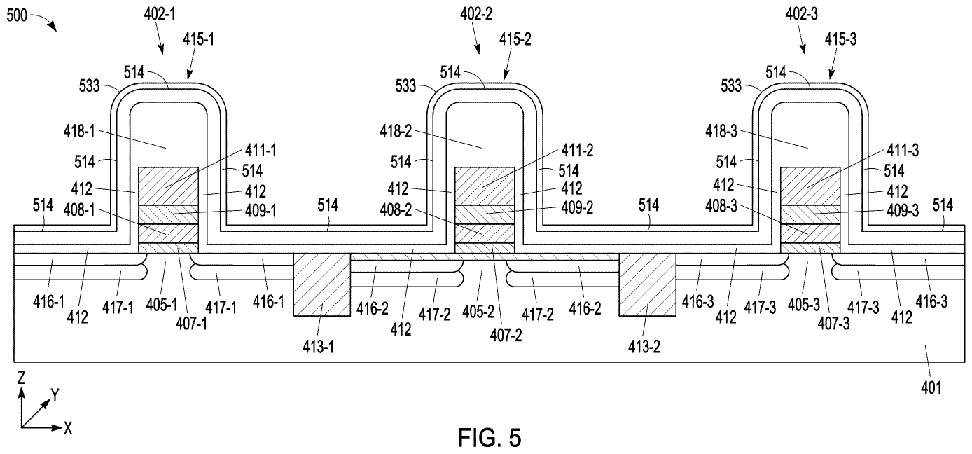

FIG. 5 illustrates a cross-sectional view of a structure 500 after processing structure 400 of FIG. 4. A hard mask 514 has been formed on spacer 412, forming a second spacer for the process flow. The material of hard mask 514 can be the same material of spacer 412. Both hard mask 514 and spacer 412 can be nitrides. An oxide layer 533 has been formed on and contacting hard mask 514.

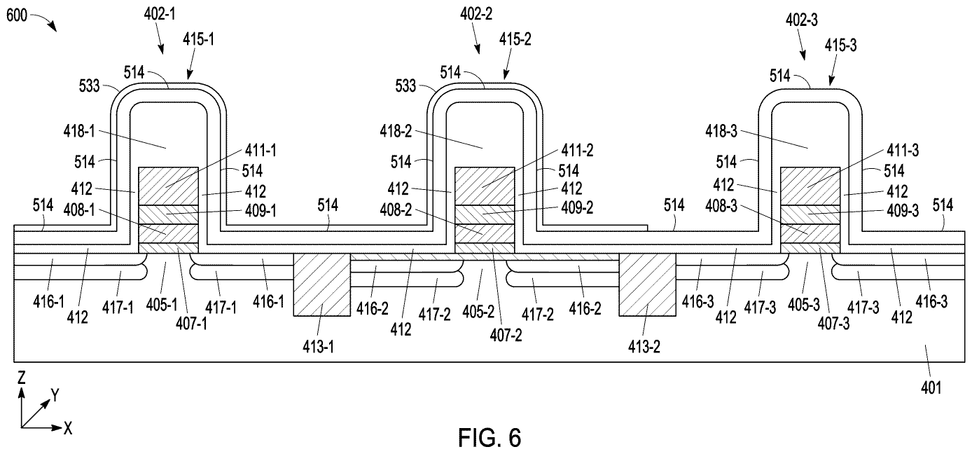

FIG. 6 illustrates a cross-sectional view of a structure 600 after processing structure 500 of FIG. 5. Photolithography has been used to form a resist patten. Using the resist pattern material has been removed from structure 500, removing portions of oxide layer 533 from around gate stack 415-3. The material removal can be conducted using a dry etch.

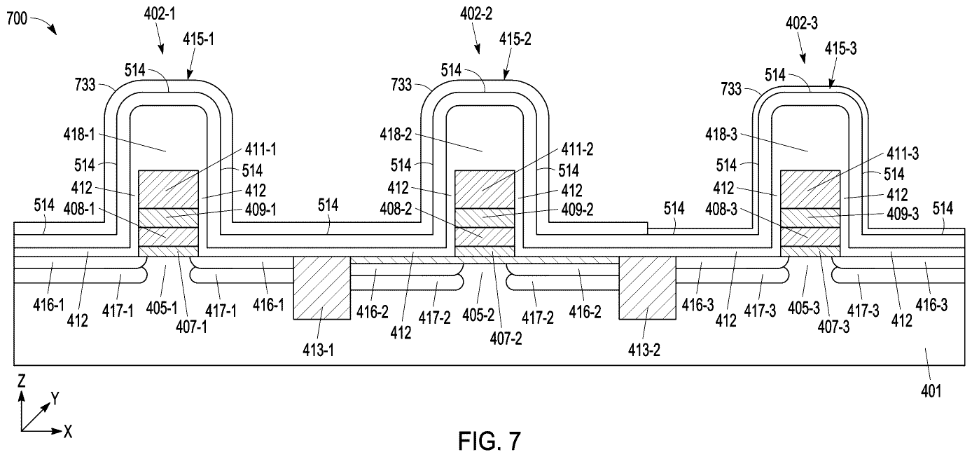

FIG. 7 illustrates a cross-sectional view of a structure 700 after processing structure 600 of FIG. 6. A second oxide layer 733 has been formed on exposed surfaces of structure 600. The portions of oxide layer 733 other than on and contacting hard mask 514 around gate stack 415-3 include first oxide layer 533. Formation of oxide layer 733 can be performed by an appropriate deposition technique.

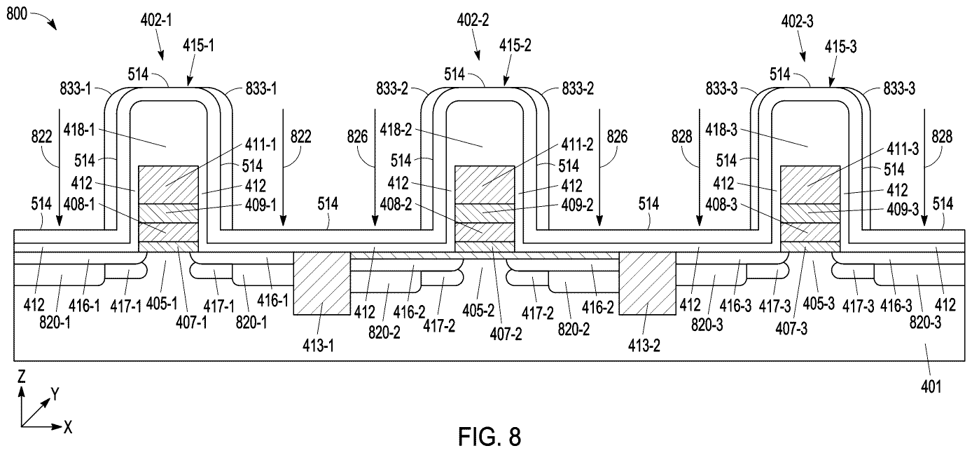

FIG. 8 illustrates a cross-sectional view of a structure 800 after processing structure 700 of FIG. 7. Oxide layer 733 has been etched, forming spacer oxide 833-1 on hard mask 514 of gate stack 415-1, forming spacer oxide 833-2 on hard mask 514 of gate stack 415-2, and forming spacer oxide 833-3 on hard mask 514 of gate stack 415-3. Source/drains 820-1, 820-2, and 820-3 for gates stacks 415-1, 415-2, and 415-3, respectively, has been formed by implantation through hard mask 514 and spacer 412. For transistor 402-1, implants have been made by implant injection 822. For transistor 402-2, implants have been made by implant injection 826. For transistor 402-3, implants have been made by implant injection 828. Implant injection 828, implant injection 826, and implant injection 822 can have different characteristics from each other. The different characteristic can be based on the transistor types of transistors 402-1, 402-2, and 402-3 being formed and the electronic device in which the transistors are being formed. Rapid thermal processing (RTP) has been performed after implanting dopants in forming source/drains 820-1, 820-2, and 820-3.

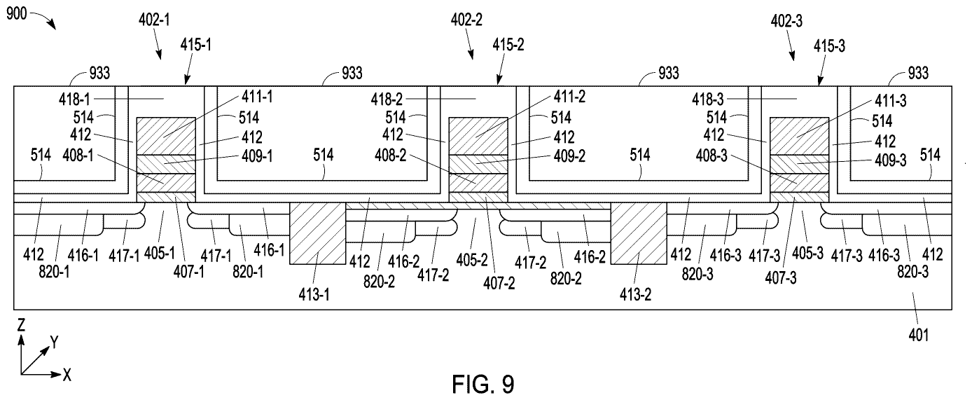

FIG. 9 illustrates a cross-sectional view of a structure 900 after processing structure 800 of FIG. 8. An ILD 933 has been formed on the exposed surfaces of structure 800. ILD 933 can be an oxide. With ILD 933 being the same oxide as spacer oxides 833-1, 833-2, and 833-3, spacer oxides 833-1, 833-2, and 833-3 are a portion of ILD 933. ILD 933 can be formed by an appropriate deposition technique. After forming ILD 933, ILD 933 was subjected to a chemical mechanical polishing (CMP) procedure.

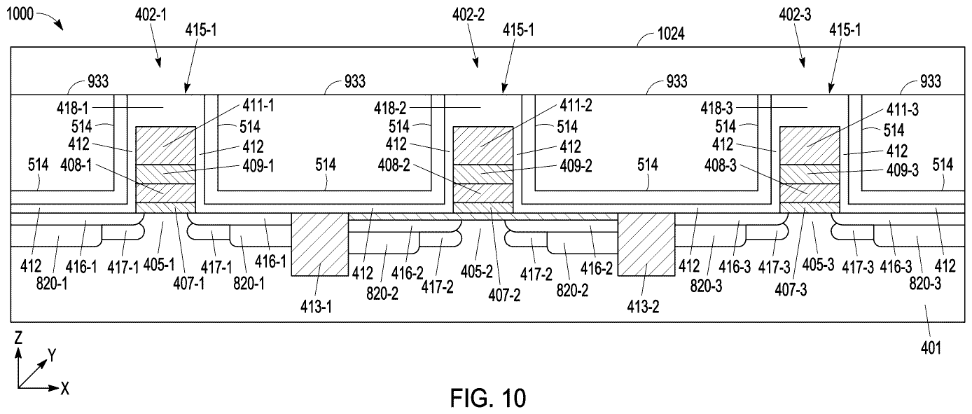

FIG. 10 illustrates a cross-sectional view of a structure 1000 after processing structure 900 of FIG. 9. An ILD structure 1024 has been formed on the exposed surfaces of structure 900. ILD structure 1024 can be a nitride layer. ILD structure 1024 extends into the memory array adjacent to the periphery in which transistors 402-1, 402-2, and 402-3 were formed. ILD structure 1024 can be formed on BLs to the memory cells of the memory array. ILD structure 1024 can be formed by chemical vapor deposition (CVD) such as, but not limited to, a CVD nitride deposition.

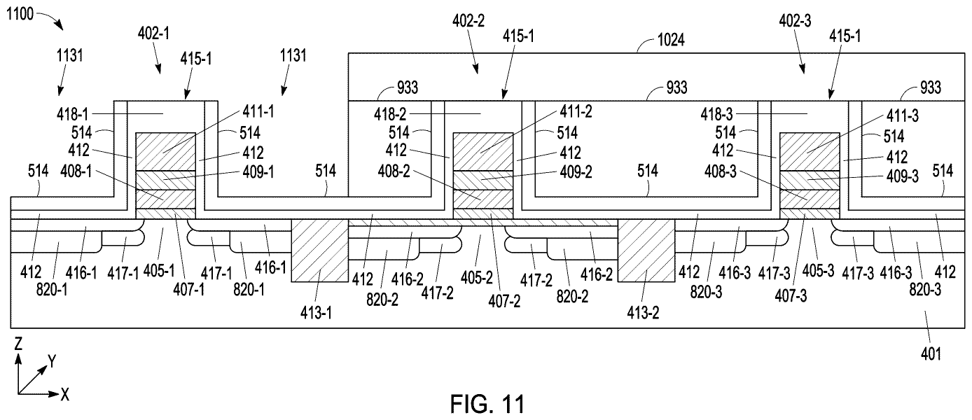

FIG. 11 illustrates a cross-sectional view of a structure 1100 after processing structure 1000 of FIG. 10. Patterning as been performed followed by material removal to create an opening 1131 about transistor 402-1 only, including the removal of ILD structure 1024 from above and around transistor 402-1. For the example process flow of FIGS. 4-10, transistor 402-1 can be a n-type transistor which has been uncovered in structure 1100, with p-type transistor 402-2 having a SiGe channel and pitch transistor 402-3 not being uncovered. Opening 1131 exposes top surfaces of cap 418-1, spacer 412, and hard mask 514 of transistor 402-1 along with portions of hard mask 514 extending horizontally from gate stack 415-1. Alternatively, transistor 402-1 can be a p-type transistor that has been uncovered.

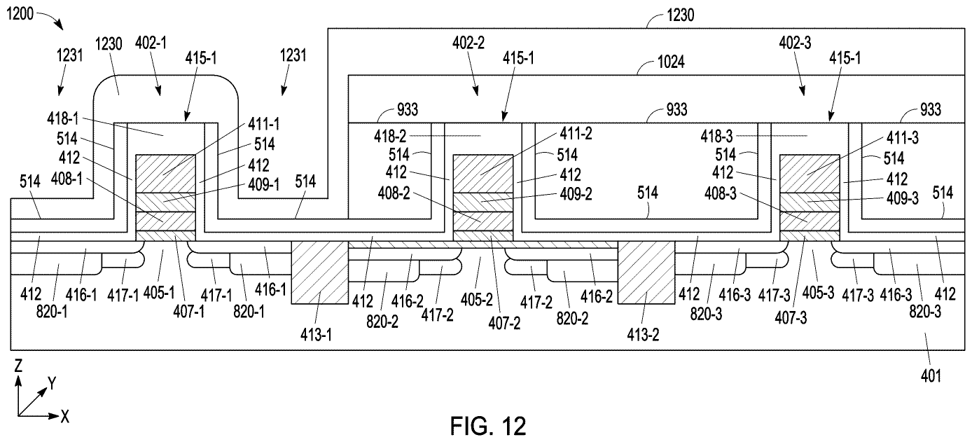

FIG. 12 illustrates a cross-sectional view of a structure 1200 after processing structure 1100 of FIG. 11. Stress material 1230 has been formed on the open surfaces of structure 1200, reducing opening 1131 to opening 1231, including being formed on ILD structure 1024 over transistors 402-2 and 402-3. For transistor 402-1 being a n-type, stress material 1230 can be material to provide tensile stress. Stress material 1230 can be formed by an appropriate technique associated with. Stress material 1230 can be deposited tensile nitride. For transistor 402-1 being a p-type transistor, stress material 1230 can be deposited compressive nitride.

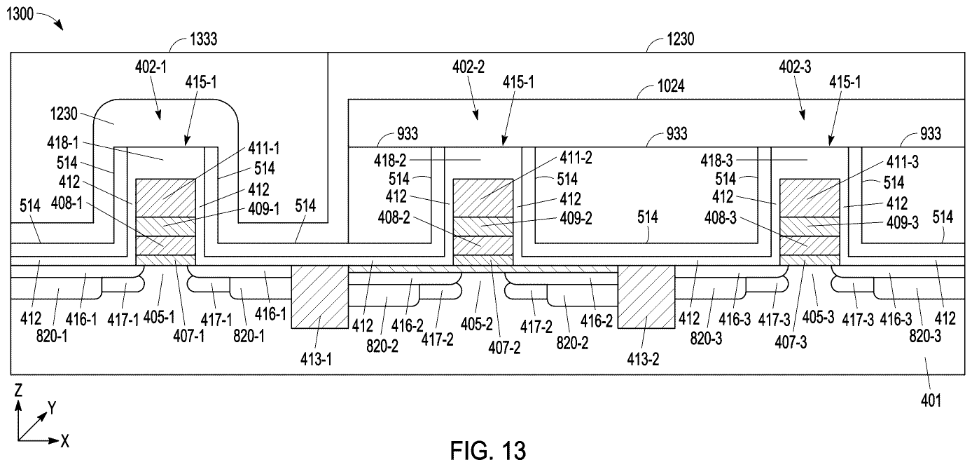

FIG. 13 illustrates a cross-sectional view of a structure 1300 after processing structure 1200 of FIG. 12. Another ILD 1333 has been formed on stress material 1230 and filling opening 1231. ILD 1333 can be an oxide, a spin-on-dielectric (SOD), a flowable CVD (FCVD) dielectric, or other appropriate dielectric to cover stress material 1230 that is on cap 418-1, spacer 412, and hard mask 514 of transistor 402-1 along with portions of hard mask 514 extending horizontally from gate stack 415-1. A CMP procedure has been performed, removing ILD 1333 from stress material 1230 such that the top surface of ILD 1333 formed in opening 1231 of structure 1200 is substantially level with the top surface of stress material 1230 on and contacting transistors 402-2 and 403-3, providing a smooth surface.

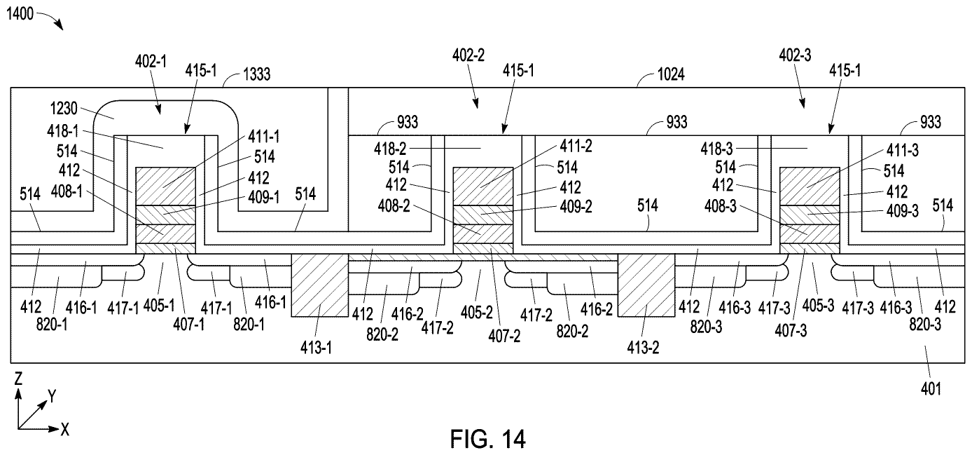

FIG. 14 illustrates a cross-sectional view of a structure 1400 after processing structure 1300 of FIG. 13. Stress material 1230 on and contacting ILD structure 1024 that is located on transistors 402-2 and 403-3 has been removed, along with portions of ILD 1333 above stress material 1230 over gate stack 415-1. Structure 1400 can be formed by a buffing CMP procedure or a non-selective etch to remove stress material 1230 from transistors 402-2 and 402-3 and other transistor structures in the periphery for which a stress material is not being formed.

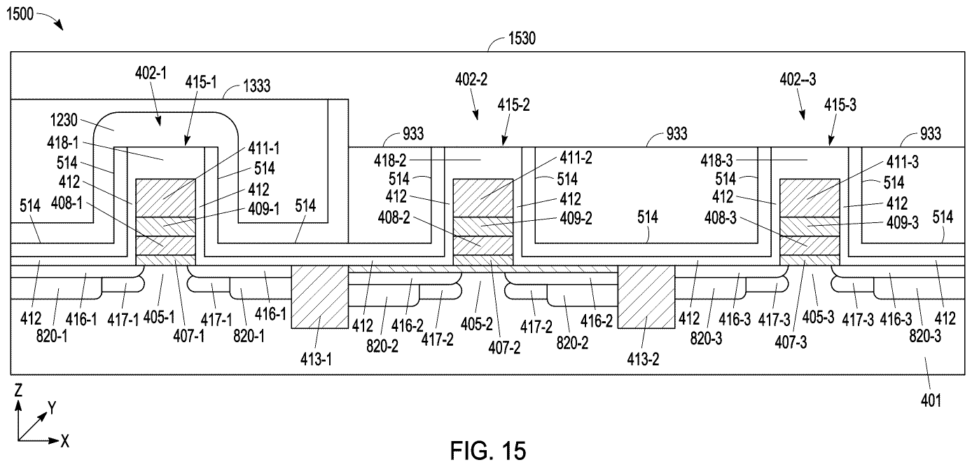

FIG. 15 illustrates a cross-sectional view of a structure 1500 after processing structure 1400 of FIG. 14. A ILD 1530 has been formed on structure 1400, providing a ILD above transistor 402-1 and increasing the ILD above transistors 402-2 and 402-3. The material of ILD 1530 can be the same as material of ILD structure 1024. ILD 1530 can be a nitride. ILD 1530 can be formed by atomic layer deposition (ALD). ILD 1530 and ILD structure 1024 can be structured as a single ILD above transistors 402-2 and 402-3 that extends to the memory array.

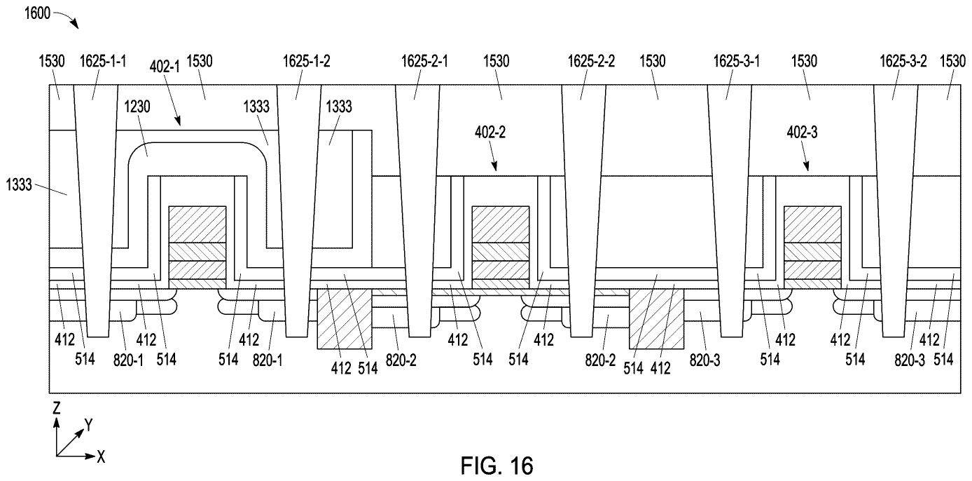

FIG. 16 illustrates a cross-sectional view of a structure 1600 after processing structure 1500 of FIG. 15. Line contacts have been formed to transistors 402-1, 402-2, and 402-3 in the periphery to the memory array. Line contacts 1625-1-1 and 1625-1-2 have been formed to source/drains 820-1 for transistor 402-1. Line contacts 1625-2-1 and 1625-2-2 have been formed to source/drains 820-2 for transistor 402-2. Line contacts 1625-2-1 and 1625-2-2 can be formed punching through SiGe of transistor 402-2, where SiGe was used to form channel structure 405-2 of transistor 402-2. Line contacts 1625-3-1 and 1625-3-2 have been formed to source/drains 820-3 for transistor 402-3. Reference labels for components of transistors 402-1, 402-2, and 402-3 shown in FIG. 15 are omitted in FIG. 16 for ease of presentation.

Various deposition techniques for components of structures 400-1600 in the process flow of FIGS. 4-16 can be used that are typical for the material being formed, the dimensions of the material being formed, and the architecture in which the material is being formed. Selective etching can be used to remove selected regions in some of the processing discussed herein. Selective etching is a process in which one or more materials are removed from a structure, while one or more other materials remain in the structure with no or little removal. Selective etching can depend on the material to be etched, the material not to be etched, the etchant employed, and the method for etching. Types of etching can include wet etching and dry etching, where each of these two basic methods can include a number of different etching procedures. In addition, conventional masking techniques, providing protective regions in the processing, can be used in various material removal procedures, as taught herein.

The following are example embodiments of devices and methods, in accordance with the teachings herein.

An example memory device 1 can comprise an array of memory cells; a transistor in a periphery to the array, the transistor including a gate stack; a dielectric cap on top of the gate stack; a dielectric sidewall vertically along the gate stack; a stress liner on the dielectric cap and on the dielectric sidewall; and an interlayer dielectric on the stress liner on the dielectric cap, the interlayer dielectric extending into the array.

An example memory device 2 can include features of example memory device 1 and can include a second transistor in the periphery having a second gate stack without an associated stress liner; a second dielectric cap on the second gate stack; and a second interlayer dielectric on and contacting the second dielectric cap, the second interlayer dielectric being a portion of the interlayer dielectric that extends from the stress liner to the array.

An example memory device 3 can include features of example memory device 2 and any of the preceding example memory devices and can include the interlayer dielectric on the stress liner having a vertical thickness less than a vertical thickness of the second interlayer dielectric.

An example memory device 4 can include features of any of the preceding example memory devices and can include the transistor having source/drains connected to vertical contacts that extend through the stress liner.

An example memory device 5 can include features of any of the preceding example memory devices and can include the transistor being a n-type field effect transistor and the stress liner is a tensile stress liner.

An example memory device 6 can include features of any of the preceding example memory devices and can include the transistor being a p-type field effect transistor and the stress liner is a compressive stress liner.

An example memory device 7 can include features of any of the preceding example memory devices and can include the stress liner to include a nitride.

An example memory device 8 can include features of any of the preceding example memory devices and can include the dielectric sidewall having two layers of dielectric material.

An example memory device 9 can include features of example memory device 8 and any of the preceding example memory devices and can include the two layers of dielectric material to include a nitride.

In an example memory device 10, any of the memory devices of example memory devices 1 to 9 may be incorporated into an electronic apparatus further comprising a host processor or memory controller and a communication bus extending between the host processor/memory controller and the memory device.

In an example memory device 11, any of the memory devices of example memory devices 1 to 10 may be modified to include any structure presented in another of example memory device 1to 10.

In an example memory device 12, any apparatus associated with the memory devices of example memory devices 1 to 11 may further include a machine-readable storage device configured to store instructions as a physical state, wherein the instructions may be used to perform one or more operations of the apparatus.

In an example memory device 13, any of the memory devices of example memory devices 1 to 12 may be formed or operated in accordance with any of the below example methods 1 to 11and methods 12 to 16.

An example method 1 of forming an memory device can comprise forming an array of memory cells; forming a transistor in a periphery to the array, the transistor including a gate stack; forming a dielectric cap on top of the gate stack; forming a dielectric sidewall vertically along the gate stack; forming a stress liner on the dielectric cap and on the dielectric sidewall; and forming an interlayer dielectric on the stress liner on the dielectric cap, the interlayer dielectric extending into the array.

An example method 2 of forming an memory device can include features of example method 1 of forming an memory device and can include forming the array of memory cells and forming the transistor method being performed together in an integrated process.

An example method 3 of forming an memory device can include features of any of the preceding example methods of forming an memory device and can include forming, in the periphery, one or more transistors without an associated stress liner, with the interlayer dielectric above the one or more transistors without an associated stress liner.

An example method 4 of forming an memory device can include features of any of the preceding example methods of forming an memory device and can include forming the stress liner to include removing an initial interlayer dielectric formed on the dielectric cap and depositing the stress liner on the dielectric cap and the dielectric sidewall.

In an example method 5, any of the example methods 1 to 4 of forming an memory device may be performed in forming an electronic apparatus further comprising a host processor and a communication bus extending between the host processor and a memory system.

In an example method 6 of forming an memory device, any of the example methods 1 to 5 of forming an memory device may be modified to include operations set forth in any other of example methods 1 to 5.

In an example method 7 of forming an memory device, any of the example methods 1 to 6 of forming an memory device may be implemented at least in part through use of instructions stored as a physical state in one or more machine-readable storage devices.

An example method 8 of forming an memory device can include features of any of the preceding example methods 1 to 7 of forming an memory device and can include performing functions associated with any features of example memory devices 1 to 13.

An example method 9 of forming an memory device can comprise forming memory cells of an array and forming a transistor in a periphery to the array in an integrated process, including forming an interlayer dielectric above the transistor extending into the array; forming, through the interlayer dielectric, an opening to a cap to a gate stack of the transistor and to a sidewall to the gate stack; forming, via the opening, a stress liner on and contacting the cap to the transistor and sidewall to the transistor; and forming, through the stress liner, contacts to the transistor.

An example method 10 of forming an memory device can include features of example method 9 of forming an memory device and can include forming, in the periphery, one or more other transistors, with the interlayer dielectric above the one or more transistors in an integrated process with forming the transistor and the interlayer dielectric; maintaining the interlayer dielectric over the one or more other transistors during the forming of the opening to the cap and sidewall to the gate stack; forming the stress liner on the interlayer dielectric above the one or more other transistors when forming the stress liner on and contacting the cap and sidewall to the transistor; removing the stress liner from the interlayer dielectric above the one or more other transistors while maintaining the stress liner on and contacting the cap and sidewall to the transistor; forming a second interlayer dielectric on the stress liner on and contacting the cap and sidewall to the transistor and on the interlayer dielectric above the one or more other transistors, the second interlayer dielectric extending into the array; and forming, through the second interlayer dielectric and through the interlayer dielectric, contacts to the one or more other transistors.

An example method 11 of forming an memory device can include features of example method 10 of forming an memory device and any of the preceding example method 9 of forming an memory device and can include forming the interlayer dielectric and the second interlayer dielectric to include forming the interlayer dielectric and the second interlayer dielectric on data lines to the memory cells of the array.

An example method 12 of forming an memory device can include features of any of the preceding example methods 9 to 11 of forming an memory device and can include forming the one or more transistors to include forming a p-type field effect transistor with a silicon germanium channel and a pitch transistor in the periphery.

An example method 13 of forming an memory device can include features of any of the preceding example methods 9 to 12 of forming an memory device and can include forming the transistor as a n-type field effect transistor and forming the stress liner as a tensile stress liner.

An example method 14 of forming an memory device can include features of any of the preceding example methods 9 to 13 of forming an memory device and can include forming the transistor as a p-type field effect transistor and forming the stress liner as a compressive stress liner.

An example method 15 of forming an memory device can include features of any of the preceding example methods 9 to 14 of forming an memory device and can include forming the stress liner to include forming a nitride stress liner.

In an example method 16 of forming an memory device, any of the example methods 9 to 15 of forming an memory device may be performed in forming an electronic apparatus further comprising a host processor and a communication bus extending between the host processor and a memory system.

In an example method 17 of forming an memory device, any of the example methods 9 to 16 of forming an memory device may be modified to include operations set forth in any other of example methods 9 to 16 of forming an memory device.

In an example method 18 of forming an memory device, any of the example methods 9 to 17 of forming an memory device may be implemented at least in part through use of instructions stored as a physical state in one or more machine-readable storage devices.

An example method 19 of forming an memory device can include features of any of the preceding example methods 9 to 18 of forming an memory device and can include performing functions associated with any features of example memory devices 1 to 13.

An example machine-readable storage device storing instructions, that when executed by one or more processors, cause a machine to perform operations, can comprise instructions to perform functions associated with any features of example memory devices 1 to 12 or perform form methods associated with any features of example methods 1 to 9 of forming an memory device or example methods 10 to 19 of forming an memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array of memory cells;
a transistor in a periphery to the array, the transistor including a gate stack;
a dielectric cap on top of the gate stack;
a dielectric sidewall vertically along the gate stack;
a stress liner on the dielectric cap and on the dielectric sidewall; and
an interlayer dielectric on the stress liner on the dielectric cap, the interlayer dielectric
extending into the array.

2. The memory device of claim 1, wherein the memory device includes:
a second transistor in the periphery having a second gate stack without an associated stress liner;
a second dielectric cap on the second gate stack; and
a second interlayer dielectric on and contacting the second dielectric cap, the second interlayer dielectric being a portion of the interlayer dielectric that extends from the stress liner to the array.

3. The memory device of claim 2, wherein the interlayer dielectric on the stress liner has a vertical thickness less than a vertical thickness of the second interlayer dielectric.

4. The memory device of claim 1, wherein the transistor has source/drains connected to vertical contacts that extend through the stress liner.

5. The memory device of claim 1, wherein the transistor is a n-type field effect transistor and the stress liner is a tensile stress liner.

6. The memory device of claim 1, wherein the transistor is a p-type field effect transistor and the stress liner is a compressive stress liner.

7. The memory device of claim 1, wherein the stress liner includes a nitride.

8. The memory device of claim 1, wherein the dielectric sidewall includes two layers of dielectric material.

9. The memory device of claim 8, wherein the two layers of dielectric material include a nitride.

10. A method of forming a memory device, the method comprising:
forming an array of memory cells;
forming a transistor in a periphery to the array, the transistor including a gate stack;
forming a dielectric cap on top of the gate stack;
forming a dielectric sidewall vertically along the gate stack;
forming a stress liner on the dielectric cap and on the dielectric sidewall; and
forming an interlayer dielectric on the stress liner on the dielectric cap, the interlayer dielectric extending into the array.

11. The method of claim 10, wherein forming the array of memory cells and forming the transistor method are performed together in an integrated process.

12. The method of claim 10, wherein the method includes forming, in the periphery, one or more transistors without an associated stress liner, with the interlayer dielectric above the one or more transistors without an associated stress liner.

13. The method of claim 10, wherein forming the stress liner includes removing an initial interlayer dielectric formed on the dielectric cap and depositing the stress liner on the dielectric cap and the dielectric sidewall.

14. A method of forming a memory die, the method comprising:
forming memory cells of an array and forming a transistor in a periphery to the array in an integrated process, including forming an interlayer dielectric above the transistor extending into the array;
forming, through the interlayer dielectric, an opening to a cap to a gate stack of the transistor and to a sidewall to the gate stack;
forming, via the opening, a stress liner on and contacting the cap to the transistor and sidewall to the transistor; and
forming, through the stress liner, contacts to the transistor.

15. The method of claim 14, wherein the method includes;
forming, in the periphery, one or more other transistors, with the interlayer dielectric
above the one or more transistors in an integrated process with forming the transistor and the interlayer dielectric;
maintaining the interlayer dielectric over the one or more other transistors during the forming of the opening to the cap and sidewall to the gate stack;
forming the stress liner on the interlayer dielectric above the one or more other transistors when forming the stress liner on and contacting the cap and sidewall to the transistor;
removing the stress liner from the interlayer dielectric above the one or more other transistors while maintaining the stress liner on and contacting the cap and sidewall to the transistor;
forming a second interlayer dielectric on the stress liner on and contacting the cap and sidewall to the transistor and on the interlayer dielectric above the one or more other transistors, the second interlayer dielectric extending into the array; and
forming, through the second interlayer dielectric and through the interlayer dielectric, contacts to the one or more other transistors.

16. The method of claim 15, wherein forming the interlayer dielectric and the second interlayer dielectric includes forming the interlayer dielectric and the second interlayer dielectric on data lines to the memory cells of the array.

17. The method of claim 15, wherein forming the one or more transistors includes forming a p-type field effect transistor with a silicon germanium channel and a pitch transistor in the periphery.

18. The method of claim 14, wherein the method includes forming the transistor as a n-type field effect transistor and forming the stress liner as a tensile stress liner.

19. The method of claim 14, wherein the method includes forming the transistor as a p-type field effect transistor and forming the stress liner as a compressive stress liner.

20. The method of claim 14, wherein forming the stress liner includes forming a nitride stress liner.
